(19) United States
(12) Patent Application Publication
(10) Pub. No.: US 2025/0234756 A1
(43) Pub. Date: Jul. 17, 2025

(54) DISPLAY DEVICE

(71) Applicant: SAMSUNG DISPLAY CO., LTD., YONGIN-SI (KR)

(72) Inventors: Hyeon Bum LEE, Yongin-si (KR); Hyun Ho KIM, Yongin-si (KR); Hyoeng Ki KIM, Yongin-si (KR)

(21) Appl. No.: 18/954,827

(22) Filed: Nov. 21, 2024

(30) Foreign Application Priority Data
Jan. 12, 2024 (KR) 10-2024-0005579

(51) Int. Cl. H10K 59/80; H10K 59/122

(52) U.S. Cl. CPC H10K 59/878; H10K 59/122; H10K 59/80518

(57) ABSTRACT

A display device includes a substrate including a display area and a non-display area, a via layer having a recess in the display area, wherein the recess includes a bottom surface and an inclined side surface which is inclined at a first angle relative to the bottom surface, and the inclined side surface connects the bottom surface to a top surface of the via layer, a first electrode including an inclined portion extending along the inclined side surface of the recess and a bottom portion extending along the bottom surface, an organic light emitting layer disposed on the first electrode, and a second electrode disposed on the organic light emitting layer. A first thickness of the inclined portion and a second thickness of the bottom portion are different.

### CROSS-REFERENCE TO RELATED APPLICATION

This application claims priority from Korean Patent Application No. 10-2024-0005579 filed on Jan. 12, 2024, in the Korean Intellectual Property Office, and all the benefits accruing therefrom under 35 U.S.C. 119, the contents of which in its entirety are herein incorporated by reference.

### BACKGROUND

### 1. Field

The present disclosure relates to a display device.

### 2. Description of the Related Art

Flat panel display devices, such as liquid crystal display devices or organic light emitting display devices, include a plurality of pairs of electric field generating electrodes and an electro-optical active layer between them. Liquid crystal display devices include a liquid crystal layer as an electro-optical active layer, and organic light emitting display devices include an organic light emitting layer as an electro-optical active layer.

Organic light emitting display devices are capable of realizing color by recombining holes and electrons injected from an anode and a cathode, respectively, and emit light during such recombination. Organic light emitting display devices have a stacked structure in which a light emitting layer is inserted between a pixel electrode, which is an anode, and a counter electrode, which is a cathode.

Recently, there are increasing cases of making each pixel into a resonance structure to improve the light extraction efficiency of organic light emitting display devices. In other words, this resonance structure consists of a semi-transmitting electrode on the imaging side of the anode and a reflective electrode on the other side of the cathode, which allows light to bounce back and forth between the two electrodes, causing enhancement interference, which results in significantly enhanced light extraction from each pixel.

However, the disadvantage of using a highly resonant structure like this is that, at the expense of increasing light extraction efficiency, the straightness of the light becomes too strong, resulting in poor viewing angle characteristics. In other words, the use of a strongly resonant structure leads to color shift depending on the viewing angle.

Therefore, to implement more reliable products, a structure that increases light extraction efficiency while maintaining good viewing angle characteristics is desirable.

### SUMMARY

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, a display device includes a substrate including a display area and a non-display area, a via layer having a recess in the display area, wherein the recess includes a bottom surface and an inclined side surface which is inclined at a first angle relative to the bottom surface, and the inclined side surface connects the bottom surface to a top surface of the via layer, a first electrode including an inclined portion extending along the inclined side surface of the recess and a bottom portion extending along the bottom surface, an organic light emitting layer disposed on the first electrode, and a second electrode disposed on the organic light emitting layer. A first thickness of the inclined portion and a second thickness of the bottom portion are different. The first thickness is measured in a first direction perpendicular to the inclined side surface of the recess, and the second thickness is measured in a second direction perpendicular to the bottom surface of the recess.

In an embodiment, the first electrode includes a first transparent conductive layer and a reflective layer. The first transparent conductive layer includes a first top portion disposed on the top surface of the via layer, a first inclined portion disposed on the inclined side surface of the recess, and a first bottom portion disposed on the bottom surface of the recess. The inclined portion includes the first inclined portion of the first transparent conductive layer. The bottom portion includes the first bottom portion of the first transparent conductive layer.

In an embodiment, an entirety of the reflective layer does not overlap the inclined portion in the second direction.

In an embodiment, the first electrode further includes a second transparent conductive layer, the second transparent conductive layer includes a second top portion, a second inclined portion, and a second bottom portion, and the second top portion is disposed between the top surface of the via layer and the first top portion, the second inclined portion is disposed between the inclined side surface and the first inclined portion, and the second bottom portion is disposed between the entirety of the reflective layer and the bottom surface of the recess.

In an embodiment, the first inclined portion connects the first top portion to the first bottom portion, and the entirety of the reflective layer is disposed above or below the first bottom portion of the first transparent conductive layer.

In an embodiment, the first electrode further includes a top portion disposed on the top surface of the via layer.

In an embodiment, the first inclined portion connects the first top portion to the first bottom portion, and the entirety of the reflective layer is disposed above or below the first bottom portion of the first transparent conductive layer.

In an embodiment, the first transparent conductive layer is formed of one of Indium Tin Oxide (ITO), Indium Zinc Oxide (IZO), Zinc Oxide (ZnO), Indium Oxide (In₂O₃), Indium Gallium Oxide (IGO), and Aluminum Zinc Oxide (AZO).

In an embodiment, the reflective layer includes at least one selected from the group consisting of silver (Ag), magnesium (Mg), chromium (Cr), gold (Au), platinum (Pt), nickel (Ni), copper (Cu), tungsten (W), and aluminum (Al).

In an embodiment, the via layer includes a first via layer defining the inclined side surface of the recess, and a second via layer defining the bottom surface of the recess and disposed on a bottom surface of the first via layer.

In an embodiment, the recess is a through hole penetrating the first via layer and exposing a top surface of the second via layer.

In an embodiment, the display device comprises a a thin film transistor disposed between the substrate and the via layer; and a planarization layer disposed below the via layer and covering the thin film transistor, wherein the first electrode is electrically connected to the thin film transistor.

In an embodiment, the display device comprises a pixel definition layer disposed on the via layer and including an opening exposing the first electrode, wherein the second electrode is disposed within the opening, and a thin film encapsulation layer disposed on the second electrode.

According to an aspect of the present disclosure, a display device includes a substrate including a display area and a non-display area, a via layer having a recess in the display area, where the recess includes a bottom surface and an inclined side surface which is inclined at a first angle relative to the bottom surface, and the inclined side surface connects the bottom surface to a top surface of the via layer, a first electrode including an inclined portion extending along the inclined side surface of the recess and a bottom portion extending along the bottom surface of the recess, an organic light emitting layer disposed on the first electrode, and a second electrode disposed on the organic light emitting layer. A first reflectance of the inclined portion is different from a second reflectance of the bottom portion.

In an embodiment, the second reflectance of the bottom portion is greater than the first reflectance of the inclined portion.

In an embodiment, the inclined portion entirely surrounds the bottom portion.

In an embodiment, the bottom portion does not vertically overlap the inclined portion.

In an embodiment, the the bottom portion includes a layer comprising at least one material selected from the group consisting of silver (Ag), magnesium (Mg), chromium (Cr), gold (Au), platinum (Pt), nickel (Ni), copper (Cu), tungsten (W), and aluminum (Al).

In an embodiment, wherein the inclined portion includes a layer formed of at least one selected from the group consisting of Indium Tin Oxide (ITO), Indium Zinc Oxide (IZO), Zinc Oxide (ZnO), Indium Oxide (In₂O₃), Indium Gallium Oxide (IGO), and Aluminum Zinc Oxide (AZO).

According to an aspect of the present disclosure, a display device includes a pixel definition layer disposed on a substrate, wherein the pixel definition layer has an opening extending from a top surface of the pixel definition layer to a bottom surface thereof, a via layer interposed between a top surface of the substrate and the bottom surface of the pixel definition layer, wherein the via layer has a recess including a bottom surface and an inclined side surface which is inclined at a first angle relative to the bottom surface, and wherein the inclined side surface connects the bottom surface of the recess to the top surface of the via layer, a first electrode including a transparent conductive layer and a reflective layer, wherein the transparent conductive layer includes a top portion disposed on the top surface of the via layer, an inclined portion disposed on the inclined side surface of the recess, and a bottom portion disposed on the bottom surface of the recess, and wherein the pixel definition layer covers an end portion of the top portion of the transparent conductive layer, an organic light emitting layer disposed on the first electrode, and a second electrode disposed on the organic light emitting layer. An entirety of the reflective layer contact the bottom portion of the transparent conductive layer.

Aspects and features of embodiments of the present disclosure provide a display device including a first electrode at an inclined portion where resonance occurs weakly and a bottom portion where resonance occurs strongly.

According to a display device according to embodiments, both light extraction efficiency and viewing angle characteristics may be improved, and thus more reliable products may be realized when employed.

However, the effects of the present disclosure are not limited to the aforementioned effects, and various other effects are included in the present specification.

### BRIEF DESCRIPTION OF THE DRAWINGS

FIG. 1 is a perspective view of a display device according to an embodiment of the present disclosure.

FIG. 2 is a plan view of a display device according to an embodiment of the present disclosure.

FIG. 3 is a cross-sectional view illustrating a portion of the cross-section taken along line I-I′ of FIG. 2 according to an embodiment of the present disclosure.

FIG. 4 is a cross-sectional view illustrating an example of the structure of a sub-pixel included in a display device according to an embodiment of the present disclosure.

FIG. 5 is a cross-sectional view illustrating an example of a via layer having the inclined structure of FIG. 4 according to an embodiment of the present disclosure.

FIG. 6 is a cross-sectional view illustrating an example of an enlarged view of the first electrode and the pixel definition film of FIG. 4 according to an embodiment of the present disclosure.

FIG. 7 is a cross-sectional view illustrating an example structure of one sub-pixel of a display device according to an embodiment of the present disclosure.

FIG. 8 is a cross-sectional view illustrating an example of a via layer having the inclined structure of FIG. 7 according to an embodiment of the present disclosure.

FIG. 9 is a cross-sectional view illustrating an example structure of one sub-pixel included in a display device according to an embodiment of the present disclosure.

FIG. 10 is a cross-sectional view illustrating an example of an enlarged view of the first electrode and the pixel definition film of FIG. 9 according to an embodiment of the present disclosure.

FIG. 11 is a cross-sectional view illustrating an example structure of one sub-pixel included in a display device according to an embodiment of the present disclosure.

FIG. 12 is a cross-sectional view illustrating one example of an enlarged view of the first electrode and the pixel definition layer of FIG. 11 according to an embodiment of the present disclosure.

FIG. 13 is a schematic diagram to illustrating a strong resonance structure in which a reflective layer is disposed between two transparent conductive layers of the first electrode according to an embodiment of the present disclosure.

FIG. 14 is a schematic diagram illustrating light emitted from a light emitting element having a strong resonant structure as shown in FIG. 13 according to an embodiment of the present disclosure.

FIG. 15 is a schematic diagram illustrating the weak resonance effect of a structure in which the first electrode is arranged with two transparent conductive layers without a reflective layer according to an embodiment of the present disclosure.

FIG. 16 is a schematic diagram illustrating light emitted from a light emitting element having the same structure as FIG. 15 according to an embodiment of the present disclosure.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, specific embodiments will be described with reference to the accompanying drawings.

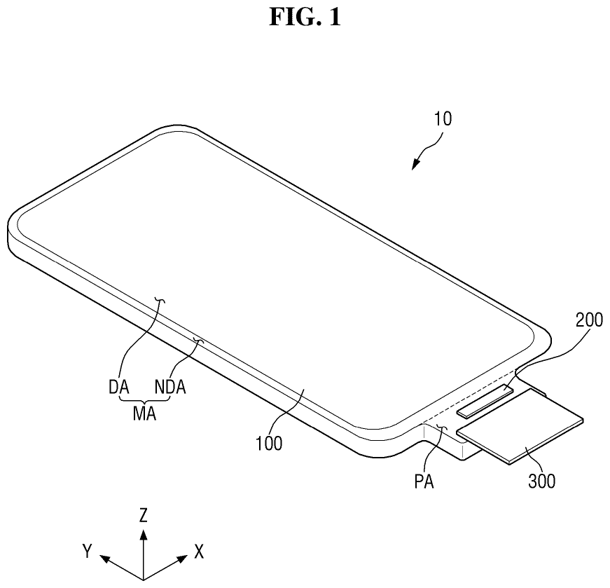

FIG. 1 is a perspective view of a display device according to an embodiment.

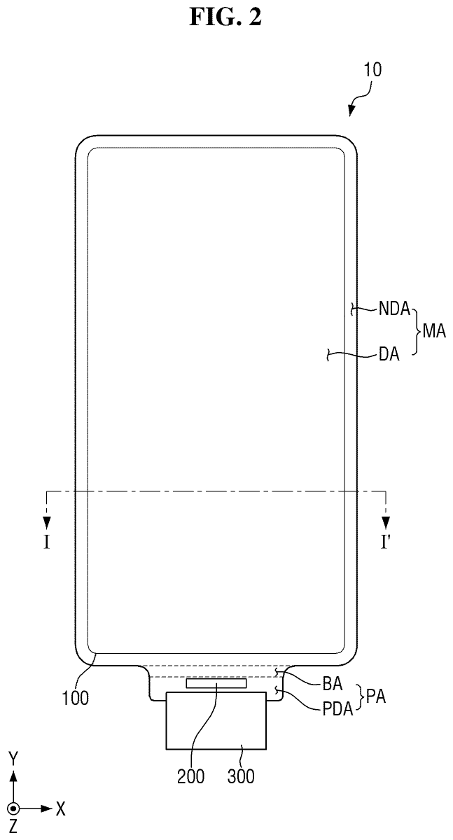

Referring to FIGS. 1 and 2, a display device 10 is a device for displaying video or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PCs (UMPC), and the like, as well as portable electronic devices such as televisions, laptops, monitors, billboards, internet of things (IoT), and other products. The display device 10 may be any one of an organic light emitting display device, a liquid crystal display device, a plasma display device, a field emission display device, an electrophoretic display device, an electrowetting display device, a quantum dot light emitting display device, and a micro LED display device. In the following, the display device 10 is described as an organic light-emitting display device, but the present disclosure is not limited thereto.

The display device 10 according to an embodiment includes a display panel 100, a display driving circuit 200, and a circuit board 300.

The display panel 100 may include a main area MA and a protruding area PA protruding from one side of the main area MA in a direction away from the main area MA.

The main area MA may be formed as a rectangular shaped plane having a short side in a first direction (X-axis direction) and a long side in a second direction (Y-axis direction) that intersects the first direction (X-axis direction). A corner where the short side in the first direction (X-axis direction) and the long side in the second direction (Y-axis direction) meet may be rounded to have a predetermined curvature or may be formed at a right angle. The planar shape of the display device 10 is not limited to a rectangular but may be formed as other polygonal, circular, or oval shapes. The main area MA may be flat, but is not limited to this, and may include curved portions formed at left and right ends. In this case, the curved portion may have a constant curvature or a changing curvature.

The main area MA may include a display area DA in which pixels are formed to display an image, and a non-display area NDA that is a peripheral area of the display area DA. For example, the non-display area NDA may be adjacent to an outer boundary of the display area DA or may surround the outer boundary of the display area DA.

In the display area DA, not only pixels but also scan lines, data lines, and power supply lines connected to the pixels may be disposed. When the main area MA includes a curved portion, the display area DA may be disposed on the curved portion. In this case, the image of the display panel 100 may be visible even on the curved portion.

The non-display area NDA may be defined as an area extending from the outside of the display area DA to the edge of the display panel 100. A scan driving portion for applying scan signals to scan lines and link lines connecting data lines to the display driving circuit 200 may be disposed in the non-display area NDA.

In the non-display area NDA of the display panel 100, an alignment mark may be placed for forming a pixel definition layer. For example, to align an opening of the pixel definition layer to a recess of a via layer, the alignment mark may be used in a photolithography process for forming the opening of the pixel definition layer. In an embodiment, four alignment marks may be placed in the non-display area NDA. However, the present disclosure is not limited thereto. The shape and size of the alignment marks may change.

The protruding area PA may protrude from one side of the main area MA. For example, the protruding area PA may protrude from a lower side of the main area MA as shown in FIG. 2. A length of the protruding area PA in the first direction (X-axis direction) may be smaller than a length of the main area MA in the first direction (X-axis direction).

The protruding area PA may include a bending area BA and a pad area PDA. In this case, the pad area PDA may be disposed on a first side of the bending area BA, and the main area MA may be disposed on a second side, opposite to the first side in the second direction (Y-axis direction), of the bending area BA. For example, the pad area PDA may be connected to a lower side of the bending area BA corresponding to the second side thereof, and the main area MA may be connected to an upper side of the bending area BA corresponding to the first side thereof.

The display panel 100 may be flexibly formed to be bent, warped, flexed, folded, or curled. Therefore, the display panel 100 may be bent in the thickness direction (Z-axis direction) in the bending area BA. In this case, before the display panel 100 is bent, one side of the pad area PDA of the display panel 100 is facing upward, but after the display panel 100 is bent, one side of the pad area PDA of the display panel 100 is facing downward. As a result, the pad area PDA is disposed on the lower part of the main area MA and may overlap the main area MA.

The pads electrically connected to the display driving circuit 200 and the circuit board 300 may be disposed in the pad area PDA of the display panel 100.

The display driving circuit 200 outputs signals and voltages to drive the display panel 100. For example, the display driving circuit 200 may supply data voltages to data lines. Additionally, the display driving circuit 200 may supply power voltage to the power supply line and scan control signals to the scan driving portion. The display driving circuit 200 may be formed as an integrated circuit (IC) and mounted on the display panel 100 in the pad area PDA using a chip on glass (COG) method, a chip on plastic (COP) method, or an ultrasonic bonding method but is not limited to this. For example, the display driving circuit 200 may be mounted on the circuit board 300.

The pads may include display pads electrically connected to the display driving circuit 200 and touch pads electrically connected to touch lines.

The circuit board 300 may be attached to the pads using an anisotropic conductive film. Thereby, the lead lines of the circuit board 300 may be a flexible film such as electrically connected to the pads. The circuit board 300 may be a flexible printed circuit board, a printed circuit board, or a chip on film.

The touch driving circuit 400 may be connected to touch electrodes of the touch sensor layer TSL of the display panel 100. The touch driving circuit 400 applies driving signals to the touch electrodes of the touch sensor layer TSL and measures capacitance values of the touch electrodes. The driving signal may be a signal having a plurality of driving pulses. The touch driving circuit 400 may not only determine whether a touch is input based on change of capacitance values, but also calculate touch coordinates where a touch is input.

The touch driving circuit 400 may be disposed on the circuit board 300. The touch driving circuit 400 may be formed as an integrated circuit (IC) and mounted on the circuit board 300.

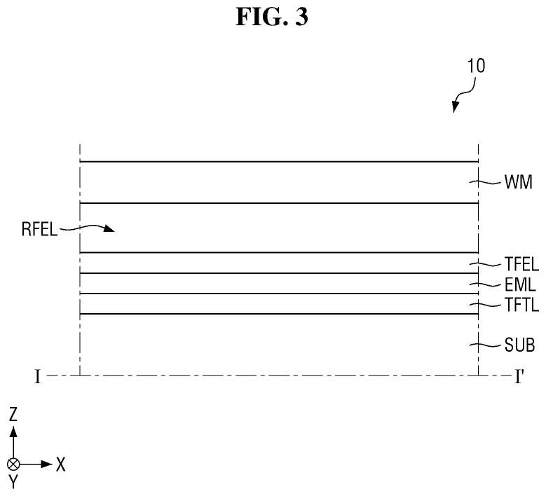

FIG. 3 is a cross-sectional view illustrating a portion of the cross-section taken along line I-I′ of FIG. 2.

Referring to FIG. 3, the display panel 100 may include a substrate SUB, a thin film transistor layer TFTL, a light emitting element layer EML, and a thin film encapsulation layer TFEL disposed on the substrate SUB. Additionally, the display panel 100 may further include a window member WM disposed on the thin film encapsulation layer RFEL.

The substrate SUB may be made of an insulating material such as glass, quartz, and polymer resin. Examples of polymer materials include polyethersulphone (PES), polyacrylate (PA), polyarylate (PAR), polyetherimide (PEI), polyethylene napthalate (PEN), polyethylene terephthalate (PET), polyphenylene sulfonate (PS), polypropylene sulfonate (PS), polypropylene terephthalate (PET), and polyphenylene sulfonate (PS), polyphenylene sulfide (PPS), polyallylate, polyimide (PI), polycarbonate (PC), cellulose triacetate (CAT), cellulose acetate propionate (CAP), or a combination thereof. Alternatively, the substrate SUB may include a metal material.

The substrate SUB may be a rigid substrate or a flexible substrate capable of bending, folding, rolling, etc. When the substrate SUB is a flexible substrate, it may be formed of polyimide (PI), but is not limited thereto.

The thin film transistor layer TFTL may be disposed on the substrate SUB. In the thin film transistor layer TFTL, not only thin film transistors of each pixel, but also scan lines, data lines, power supply lines, scan control lines, and routing lines connecting pads to data lines will be formed. Each of the thin film transistors may include a gate electrode, a semiconductor layer, a source electrode, and a drain electrode.

The thin film transistor layer TFTL may be disposed in the display area DA and the non-display area NDA. Specifically, thin film transistors, scan lines, data lines, and power supply lines of each pixel of the thin film transistor layer TFTL may be disposed in the display area DA. The scan control lines and link lines of the thin film transistor layer TFTL may be disposed in the non-display area NDA.

A light emitting element layer EML may be disposed on the thin film transistor layer TFTL. The light emitting layer EML may include pixels including a first electrode, a light emitting layer, and a second electrode, and a pixel definition layer defining each of the pixels. For example, the pixel definition layer may include openings each of which a light emitting area of a corresponding pixel among the pixels. The light emitting layer may be an organic light emitting layer containing an organic material. In this case, the light emitting layer may include a hole transporting layer, an organic light emitting layer, and an electron transporting layer. When a predetermined voltage is applied to the first electrode through the thin film transistor of the thin film transistor layer TFTL and a cathode voltage is applied to the second electrode, holes and electrons are transported to the organic light emitting layer through the hole transport layer and the electron transport layer, respectively, and are combined with each other in the organic light emitting layer to emit light. The pixels of the light emitting element layer EML may be disposed in the display area DA.

A thin film encapsulation layer TFEL may be disposed on the light emitting element layer EML. The thin film encapsulation layer TFEL serves to prevent oxygen or moisture from penetrating into the light emitting element layer EML. To this end, the thin film encapsulation layer TFEL may include at least one inorganic film. The inorganic film may be a silicon nitride layer, a silicon oxynitride layer, a silicon oxide layer, a titanium oxide layer, or an aluminum oxide layer but is not limited thereto. Additionally, the thin film encapsulation layer TFEL serves to protect the light emitting element layer EML from debris such as dust. For this purpose, the thin film encapsulation layer TFEL may include at least one organic film. The organic film may be an acryl resin, an epoxy resin, a phenolic resin, a polyamide resin, or a polyimide resin but is not limited thereto.

The thin film encapsulation layer TFEL may be disposed in both the display area DA and the non-display area NDA. Specifically, the thin film encapsulation layer TFEL may be disposed to cover the light emitting element layer EML in the display area DA and the non-display area NDA and may be disposed to cover the thin film transistor layer TFTL in the non-display area NDA.

The window member WM may be disposed on the thin film encapsulation layer TFEL and may be optically transparent. Accordingly, the image generated in the display panel DP may pass through the window member WM.

Additional structures may be further disposed between the window member WM and the thin film encapsulation layer TFEL. For example, a touch sensing layer or a micro lens array layer may be further disposed. The micro lens array layer may include a plurality of pixels and a plurality of micro lenses. For example, in the micro lens array, each of the plurality of micro lenses may overlap a corresponding one of the plurality of pixels. Each of the plurality of micro lenses has a predetermined radius of curvature, magnifies the image output from the display panel DP, and then projects the magnified image on a virtual plane (not shown).

In this case, a transparent adhesive member such as an optically clear adhesive OCA film may be further disposed between the window member WM and the lower layer.

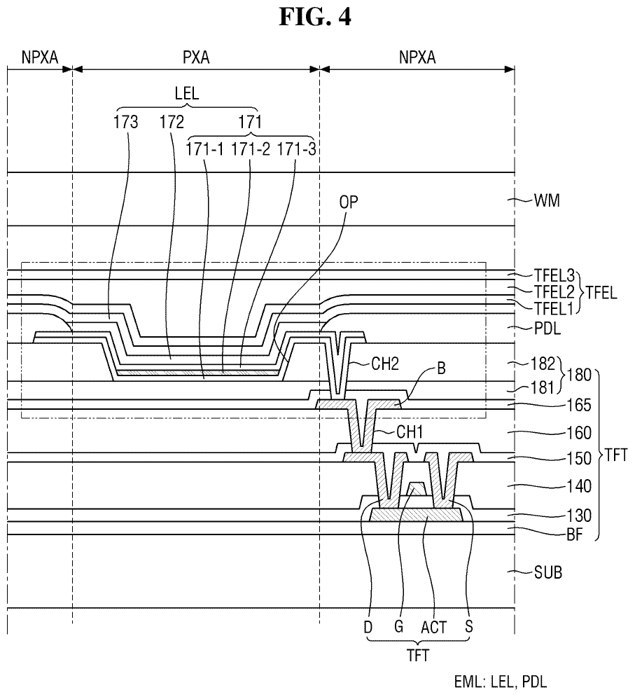

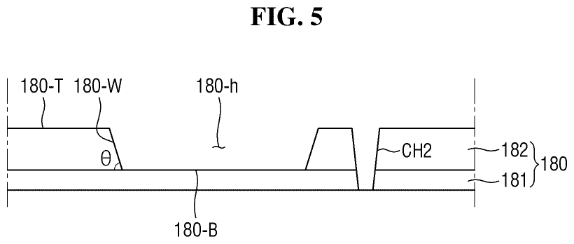

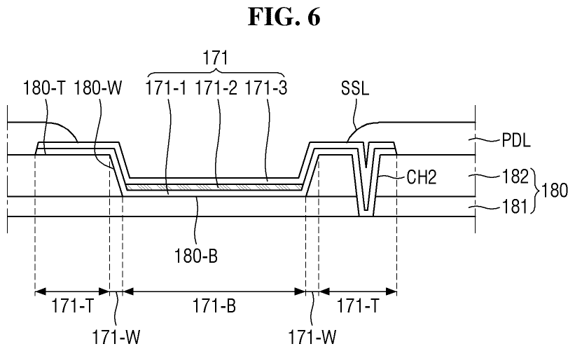

FIG. 4 is a cross-sectional view illustrating an example of the structure of a sub-pixel included in a display device according to an embodiment of the present disclosure. FIG. 5 is a cross-sectional view illustrating an example of a via layer having the inclined structure of FIG. 4. FIG. 6 is a cross-sectional view illustrating an example of an enlarged view of the first electrode and the pixel definition layer of FIG. 4.

A pixel may include a plurality of light emitting elements LEL and may be defined as the minimum light emitting unit capable of displaying white light by combining light emitted by a plurality of light emitting elements LEL.

A pixel may include a plurality of sub-pixels. Each of the plurality of sub-pixels may display light of different wavelengths.

Each of the sub-pixels represents a region where a first electrode 171, an organic light emitting layer 172, and a second electrode 173 sequentially stacked so that holes from the first electrode 171 and electrons from the second electrode 173 are combined with each other in the organic light emitting layer 172 to emit light. Each of the sub-pixels may include a light emitting element LEL.

The first electrode 171 may function as an anode electrode, and the second electrode 173 may function as a cathode electrode. However, it is not limited to this, and the polarities of the first electrode 171 and the second electrode 173 may be opposite to each other.

Referring to FIGS. 4 to 6, a thin film transistor layer TFTL is formed on the substrate SUB of the display device 10. The thin film transistor layer TFTL includes a buffer layer BF, thin film transistors TFT, a gate insulating layer 130, an interlayer insulating layer 140, a first protective layer 150, a planarization layer 160, and a second protective layer 165, and a via layer 180. The via layer 180 may also be referred to as an insulating layer.

The buffer layer BF may be formed on one surface of the substrate SUB. The buffer layer BF may be formed on one side (e.g., a top surface) of the substrate SUB to protect the thin film transistors TFT and the organic light emitting layer 172 of the light emitting element layer EML from moisture penetrating through the substrate SUB, which is vulnerable to moisture permeation. In an embodiment, the buffer layer BL may contact the top surface of the substrate SUB. The buffer layer BF may be composed of a plurality of inorganic films alternately stacked. For example, the buffer layer BF may be formed as a multilayer of alternately stacked inorganic films of one or more of a silicon nitride layer, a silicon oxynitride layer, a silicon oxide layer, a titanium oxide layer, and an aluminum oxide layer. The buffer layer BF may be omitted.

The thin film transistor TFT is formed on the buffer layer BF. The thin film transistor TFT includes an active layer ACT, a gate electrode G, a source electrode S, and a drain electrode D. In FIG. 4, the thin film transistor TFT is formed in a top gate manner in which the gate electrode G is located on top of the active layer ACT. However, the present disclosure is not limited to the thin film transistor TFT which is formed in the top gate manner. In an embodiment, thin film transistors TFT may be formed in a bottom gate manner where the gate electrode G is located at the bottom of the active layer ACT or in a double gate method where the gate electrode G is located at both the top and bottom of the active layer ACT.

The active layer ACT is formed on the buffer layer BF. The active layer ACT may include or may be formed of a binary compound (ABx), a ternary compound (ABxCy), or a quaternary compound (ABxCyDz) containing indium, zinc, gallium, tin, titanium, aluminum, hafnium (Hf), zirconium (Zr), magnesium (Mg), or the like. For example, the active layer ACT may include or may be formed of ITZO (an oxide comprising indium, tin, and titanium) or IGZO (an oxide comprising indium, gallium, and tin). A light blocking layer may be formed in a space between the buffer layer and the active layer ACT to block external light incident on the active layer ACT.

The gate insulating layer 130 may be formed on the active layer ACT. The gate insulating layer 130 may be formed of an inorganic film, such as a silicon nitride layer, a silicon oxynitride layer, a silicon oxide layer, a titanium oxide layer, and an aluminum oxide layer.

The gate electrode G and a gate line may be formed on the gate insulating layer 130. The gate electrode G and the gate line may be formed as a single layer of any one of molybdenum (Mo), aluminum (Al), chromium (Cr), gold (Au), titanium (Ti), nickel (Ni), neodymium (Nd), and copper (Cu), and an alloy thereof or multiple layers each of which is formed of one of the listed materials.

The interlayer insulating layer 140 may be formed on the gate electrode G and the gate line. The interlayer insulating layer 140 may be formed of an inorganic film, for example, a silicon nitride layer, a silicon oxynitride layer, a silicon oxide layer, a titanium oxide layer, or an aluminum oxide layer.

The source electrode S and the drain electrode D may be formed on the interlayer insulating layer 140. Each of the source electrode S and the drain electrode D may be connected to the active layer ACT through a contact hole penetrating the gate insulating layer 130 and the interlayer insulating layer 140. The source electrode S and drain electrode D may be formed as a single layer of one of molybdenum (Mo), aluminum (Al), chromium (Cr), gold (Au), titanium (Ti), nickel (Ni), neodymium (Nd), and copper (Cu), and an alloy thereof or multiple layers each of which is formed of one of the listed materials.

The first protective layer 150 may be formed on the source electrode S and the drain electrode D to insulate the thin film transistor TFT. The first protective layer 150 may be formed of an inorganic film, for example, a silicon nitride layer, a silicon oxynitride layer, a silicon oxide layer, a titanium oxide layer, or an aluminum oxide layer.

The planarization layer 160 may be formed on the first protective layer 150 to flatten a step caused by the thin film transistor TFT. For example, the planarization layer 160 may provide a flat upper surface for a subsequent process.

The planarization layer 160 may be formed of an organic film such as an acrylic resin, an epoxy resin, a phenolic resin, a polyamide resin, a polyimide resin, and the like.

The connection electrode B may be formed on the planarization layer 160. The connection electrode B may be connected to the drain electrode D of the thin film transistor TFT through a first contact hole CH1 penetrating the planarization layer 160 and the first protective layer 150. The connection electrode B may be formed as a single layer of one of molybdenum (Mo), aluminum (Al), chromium (Cr), gold (Au), titanium (Ti), nickel (Ni), neodymium (Nd), and copper (Cu), and an alloy thereof, or multiple layers each of which is formed of one of the listed materials.

The second protective layer 165 may be formed on the connection electrode B to insulate the thin film transistor TFT. The second protective layer 165 may be formed of an inorganic film, for example, a silicon nitride layer, a silicon oxynitride layer, a silicon oxide layer, a titanium oxide layer, or an aluminum oxide layer. In an embodiment, one or more of the first protective layer 150 and the second protective layer 165 may be omitted.

The via layer 180 may be disposed on the second protective layer 165. The via layer 180 may be formed of an organic material, for example, an acrylic resin, an epoxy resin, a phenolic resin, a polyamide resin, a polyimide resin, or the like.

The via layer 180 includes an inclined structure. The inclined structure may include an inclined portion 180-W having an inclination angle θ and a bottom surface 180-B extending from a bottom of the inclined portion 180-W. The inclination angle θ refers to an angle formed between an extension of the bottom surface 180-B of the inclined structure and the inclined portion 180-W of the inclined structure and may be adjusted by a process. As the inclined structure includes an inclined portion 180-W having an inclined angle θ, the inclined structure may have a substantially wider upper width relative to a lower width. In some embodiments, the inclination angle θ may have an angle selected from a range from about 20 degrees to about 70 degrees relative to an extension of the bottom surface but is not limited thereto. Additionally, the inclined structure may further include a top portion 180-T extending from the upper end of the inclined portion 180-W.

In an embodiment, the via layer 180 may be made of a plurality of insulating films. The via layer 180 may include a first via layer 181 and a second via layer 182.

The first via layer 181 may be a single insulating film or multiple insulating films with a flat top surface. The second via layer 182 is disposed on the first via layer 181, and the second via layer 182 may include a through hole exposing the first via layer 181. The through hole 180-h may be formed to become narrower downward. Accordingly, the second via layer 182 and the first via layer 181 have an inclined structure due to the through hole 180-h. A side surface of the through hole 180-h may be the inclined portion 180-W of the inclined structure, and the first via layer 181 exposed by the through hole 180-h may be the bottom surface 180-B of the inclined structure, and the upper surface of the second via layer 182 surrounding the through-hole 180-h may be the top portion 180-T of the inclined structure. The through hole 180-h may be referred to as a recess in the via layer 180.

The first via layer 181 and the second via layer 182 may be formed of the same or similar material. In some embodiments, the first via layer 181 and the second via layer 182 may be formed of different materials. In some embodiments, the first via layer 181 and the second via layer 182 may be formed of an acryl resin, an epoxy resin, a phenolic resin, a polyamide resin, or a polyimide resin but is not limited thereto.

The light emitting element layer EML may be disposed on the thin film transistor layer TFTL. The light emitting element layer EML may include light emitting elements LEL and a pixel definition layer PDL.

Each of the light emitting elements LEL may include a first electrode 171, an organic light emitting layer 172, and a second electrode 173.

The first electrode 171 is disposed on the via layer 180. Since the first electrode 171 is disposed along the inclined structure of the via layer 180, the first electrode 171 may also have an inclined structure. The first electrode 171 may have an inclined portion 171-W, a bottom portion 171-B, and a top portion 171-T overlapping the inclined portion 180-W, the bottom portion 180-B, and the top portion 180-T of the via layer 180, respectively. The inclined portion 171-W of the first electrode 171 may have the same or similar angle as the inclined portion 180-W of the via layer 180. As the first electrode 171 is disposed on the inclined structure of the via layer 180, the first electrode 171 may have a concave shape. The inclined portion 171-W surrounds the entire bottom portion 171-B, and the inclined portion 171-W and the bottom portion 171-B do not overlap vertically. The bottom portion 171-B and the top portion 171-T of the first electrode 171 may have a flat surface. The present disclosure is not limited thereto. In an embodiment, the bottom portion 171-B and the top portion 171-T of the first electrode 171 may have a curved surface with a curvature. Even in this case, the bottom portion 171-B and the top portion 171-T may be formed to be relatively flat compared to the inclined portion 171-W.

When light generated from the organic light emitting layer 172 is incident on the inclined portion 171-W of the first electrode 171, the incident light may be reflected by the first electrode 171 and emitted to the outside. At this case, the inclination angle θ may be adjusted so that the light generated from the organic light emitting layer 172 may be emitted in a desired direction. Accordingly, the efficiency of light emitted to the outside from the light emitting element LEL having an inclined structure may be improved.

The first electrode 171 may include the inclined portion 171-W and the bottom portion 171-B with different numbers of layers. The bottom portion 171-B may include a greater number of layers than the inclined portion 171-W. For example, the inclined portion 171-W of the first electrode 221 may include two transparent conductive layers 171-1 and 171-3, and the bottom portion 171-B may include a reflective layer 171-2 disposed between the multiple transparent conductive layers 171-1 and 171-3. Further, the top portion 171-T of the first electrode 221 may include the two transparent conductive layers 171-1 and 171-3, like the inclined portion 171-W.

Each of the transparent conductive layers 171-1 and 171-3 is a transparent conductive film with a high work function and a small hole injection barrier and may be formed of at least one of the following materials selected from the group consisting of indium tin oxide (ITO), indium zinc oxide (IZO), zinc oxide (ZnO), indium tin oxide (In₂O₃), indium gallium oxide (IGO), aluminum zinc oxide (AZO), and an equivalent thereof. In addition, the reflective layer 171-2 may include or may be formed of at least one selected from the group consisting of silver (Ag), magnesium (Mg), chromium (Cr), gold (Au), platinum (Pt), nickel (Ni), copper (Cu), tungsten (W), and aluminum (Al). In some embodiments, the inclined portion 171-W and the top portion 171-T of the first electrode 171 may be a two-layer structure formed of the two transparent conductive layers 171-1 and 171-3, and the bottom portion 171-B of the first electrode 171 may be a three-layer structure of the two transparent conductive layers 171-1 and 171-3 and the reflective layer 171-2 interposed therebetween. In an embodiment, each of the two transparent conductive layers 171-1 and 171-3 may be formed of ITO, and the reflective layer 171-2 may be formed of Au. In this case, the first electrode 171 may be a stacked layer of ITO/Ag/ITO.

The first electrode 171 may be electrically connected to the drain electrode D of the thin film transistor TFT through a second contact hole CH2 penetrating the via layer 180. In an embodiment, the drawing shows that the second contact hole CH2 is formed at the bottom surface of the top portion 171-T but is not limited thereto. The second contact hole CH2 may be formed on the bottom surface of the inclined portion 171-W or the bottom portion 171-B of the first electrode 171.

At least a portion of the top portion 171-T of the first electrode 171 may be covered by the pixel definition layer PDL. For example, the top portion 171-T of the first electrode 171 may have end portions covered by the pixel definition layer PDL.

The pixel definition layer PDL may be formed to compartmentalize the light emitting area PXA and the non-emitting area NPXA. The pixel definition layer PDL may be formed to cover the edge portion of the first electrode 171. The pixel definition layer PDL may be formed of an organic film such as an acrylic resin, epoxy resin, phenolic resin, polyamide resin, polyimide resin, and the like.

An inclined surface SSL of the pixel definition layer PDL may have a curved surface. A slope of the curved surface with respect to the top surface of the via layer VIA may reduce toward a top surface of the pixel definition layer PDL.

The organic light emitting layer 172 is formed on the first electrode 171.

The organic light emitting layer 172 may be disposed to overlap the top portion 171-T, the inclined portion 171-W, and the bottom portion 171-B of the first electrode 171. Accordingly, the organic light emitting layer 172 may also have an inclined portion overlapping the inclined portion 171-W of the first electrode 171 and a bottom portion overlapping the bottom portion 171-B of the first electrode 171.

In an embodiment, the organic light emitting layer 172 may emit one of red light, green light, and blue light. The wavelength of red light may be about 620 nm to 750 nm, and the wavelength of green light may be from about 495 nm to 570 nm. Additionally, the wavelength of blue light may be from about 450 nm to 495 nm.

In an embodiment, the organic light emitting layer 172 may emit white light. When the organic light emitting layer 172 emits white light, the organic light emitting layer 172 may have a red light emitting layer, a green light emitting layer, and a blue light emitting layer stacked together. In an embodiment, a separate color filter for displaying red, green, and blue may be included.

Although not shown in the drawing, the organic light emitting layer 172 may have a multilayer structure including a hole transporting layer, an organic light emitting layer, and an electron transporting layer.

The second electrode 173 is formed on the organic light emitting layer 172 and the pixel definition layer PDL. The second electrode 173 may be formed to cover the organic light emitting layer 172 and the pixel definition layer PDL. The second electrode 173 may be a common layer commonly formed in all light emitting elements LEL. In an embodiment, the second electrode 173 may be a cathode electrode. The second electrode 173 may include at least one selected from the group consisting of Li. Ca, Lif/Ca, LiF/Al, Al, Ag, and Mg. The second electrode 173 may be made of a metal thin film with a low work function. The second electrode 173 may be a transparent or translucent electrode comprising one or more selected from the group consisting of Indium Tin Oxide (ITO), Indium Zinc Oxide (IZO), Zinc Oxide (ZnO), Indium Oxide (In₂O₃), Indium Gallium Oxide (IGO), and Aluminum Zinc Oxide (AZO).

In the upper light emitting structure, the second electrode 173 may be formed of a transparent conductive oxide (TCO), such as indium tin oxide (ITO) and indium zinc oxide (IZO), which can transmit light, or a semi-transmissive conductive material, such as magnesium (Mg), silver (Ag), and an alloy of magnesium (Mg) and silver (Ag). When the second electrode 173 is formed of a semi-transmissive metal material, a micro cavity may be formed at the second electrode 173 to increase the light output efficiency.

An encapsulation layer TFEL may be disposed on the second electrode 173. The encapsulation layer TFEL may include at least one inorganic film to prevent oxygen or moisture from penetrating into the organic light emitting layer 172 and the second electrode 173. Additionally, the encapsulation layer TFEL may include at least one organic film to protect the light emitting element layer EML from debris, such as dust. For example, the encapsulation layer TFEL may include a first inorganic film TFE1 disposed on the second electrode 173, an organic film TFE2 disposed on the first inorganic film TFE1, and a second inorganic film TFE3 disposed on the organic film TFE2. The first inorganic film TFEL and the second inorganic film TFE3 may be formed of a silicon nitride layer, a silicon oxynitride layer, a silicon oxide layer, a titanium oxide layer, or an aluminum oxide layer but are not limited thereto. The organic film may be formed of an acrylic resin, an epoxy resin, a phenolic resin, a polyamide resin, a polyimide resin, or the like but is not limited thereto.

A second buffer layer may be formed on the thin film encapsulation layer TFEL. The second buffer layer may be composed of a plurality of inorganic films alternately stacked. For example, the second buffer layer may be formed as a multilayer of alternately stacked inorganic films of one or more of a silicon nitride layer, a silicon oxynitride layer, a silicon oxide layer, a titanium oxide layer, and an aluminum oxide layer. The second buffer layer may be omitted.

Each pixel area PA of the display panel DP may include a light emitting area PXA and a light non-emitting area NPXA. The light emitting area PXA is an area in each pixel area PA where the organic light emitting layer 172 that emits actual light is disposed, and the non-emitting area NPXA may be a light blocking area adjacent to the light emitting area PXA and where a light blocking material such as a black matrix is disposed. For example, the light-emitting area (PXA) is a region within each pixel area (PA) where the organic light emitting layer (172) is located and emits light. Adjacent to the PXA, the non-emitting area (NPXA) serves as a light-blocking region. In an embodiment, the light emitting area PXA may be formed wider than an opening OP defined by the pixel definition layer PDL.

As such, the display device according to an embodiment includes an inclined portion 171-W and a bottom surface 180-B extending downwardly from the inclined portion 171-W, and the reflectivity of the bottom surface 180-B is higher than the reflectivity of the inclined portion 171-W.

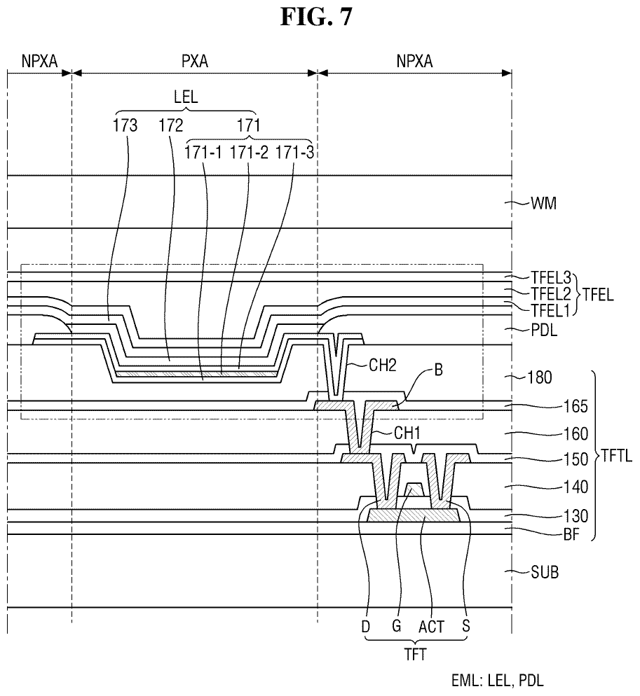

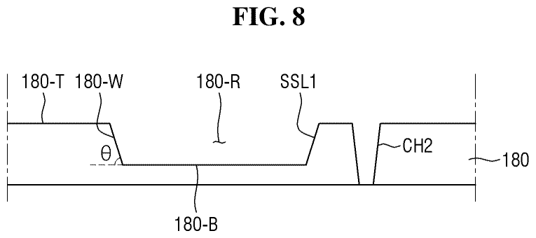

FIG. 7 is a cross-sectional view illustrating an example structure of one sub-pixel of a display device according to an embodiment of the present disclosure. FIG. 8 is a cross-sectional view illustrating an example of a via layer having the inclined structure of FIG. 7.

Referring to FIGS. 7 and 8, it is different from the embodiment described with reference to FIGS. 4 and 5 in that the via layer 180 is formed as a single layer and has an inclined structure implemented by a recess 180-R.

Referring to FIGS. 7 and 8, the via layer 180 is formed as a single layer and has an inclined surface SSL1 defining a downwardly concave recess 180-R. Further, the inclined surface SSL1 of the via layer 180 may have a slope with respect to the top surface of the via layer 180. The inclined surface SSL1 of the via layer 180 which corresponds to a downwardly extending line of the recess 180-R may have an inclination angle θ relative to a bottom surface 180-B of the recess 180-R. The inclination angle θ may be an acute angle relative to a bottom surface 180-B of the recess 180-R. The inclination angle θ may have an angle selected from a range from about 20 degrees to about 70 degrees but is not limited thereto. The recess 180-R may have an upper width that is substantially wider than the lower width. As such, the via layer 180 may have an inclined structure defined by the recess 180-R. Accordingly, the inclined structure may include an inclined portion 180-W disposed on the inclined surface SSL1 of the recess 180-R and having an inclination angle θ, a bottom portion 180-B extending horizontally from a lower end of the inclined surface SSL1 of the recess 180-R, and the inclined structure may further include a top portion 180-T extending horizontally from an upper end of the inclined surface SSL1 of the recess 180-R.

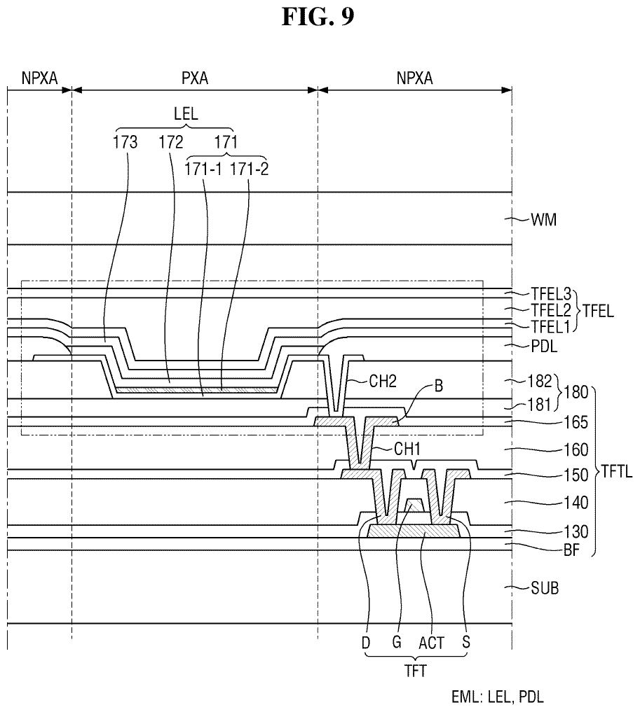

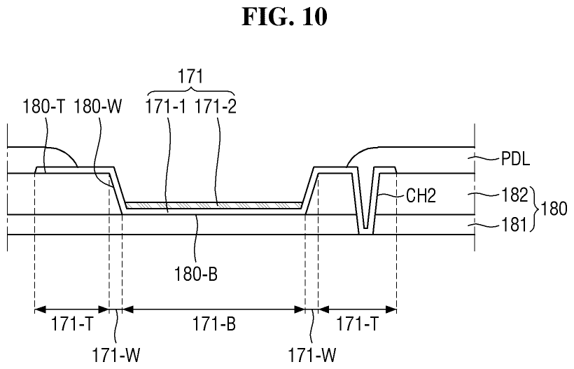

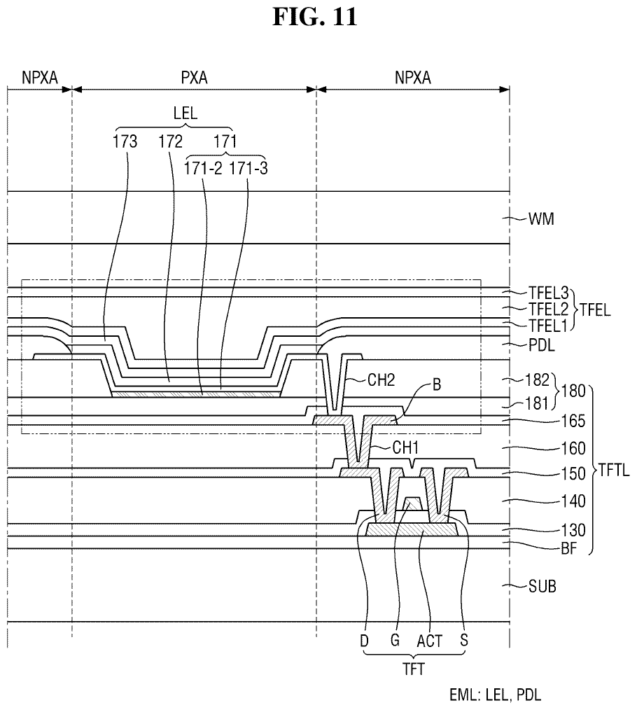

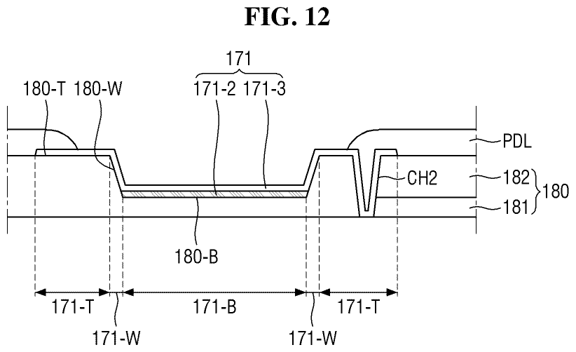

FIG. 9 is a cross-sectional view illustrating an example structure of one sub-pixel included in a display device according to an embodiment of the present disclosure. FIG. 10 is a cross-sectional view illustrating an example of an enlarged view of the first electrode and the pixel definition film of FIG. 9. FIG. 11 is a cross-sectional view illustrating an example structure of one sub-pixel included in a display device according to an embodiment of the present disclosure. FIG. 12 is a cross-sectional view illustrating one example of an enlarged view of the first electrode and the pixel definition layer of FIG. 11.

Referring to 9 to 12, the first electrode 171 is different from the embodiment described with reference to FIGS. 4 and 5 in that it has a single layer of transparent electrode layer.

First, referring to FIGS. 9 and 10, the first electrode 171 includes a reflective layer 171-2 and a single layer of transparent conductive layer 171-1 disposed below the reflective layer 171-2. The transparent conductive layer 171-1 may be electrically connected to the drain electrode D of the thin film transistor TFT through the second contact hole CH2. The transparent conductive layer 171-1 is disposed at the inclined portion 171-W, the bottom portion 171-B, and the top portion 180-T. The reflective layer 171-2 is disposed on the bottom portion 171-B only, and the reflective layer 171-2 may be in direct contact with the transparent conductive layer 171-1.

Referring to FIGS. 11 and 12, the first electrode 171 includes a reflective layer 171-2 and a single layer of transparent conductive layer 171-3 disposed on the reflective layer 171-2. The transparent conductive layer 171-3 may be electrically connected to the drain electrode D of the thin film transistor TFT through the second contact hole CH2. The reflective layer 171-2 is disposed on the bottom portion 171-B only, and the transparent conductive layer 171-3 is disposed on the inclined portion 171-W, the bottom portion 171-B, and the top portion 180-T. The reflective layer 171-2 may be in direct contact with the transparent conductive layer 171-3.

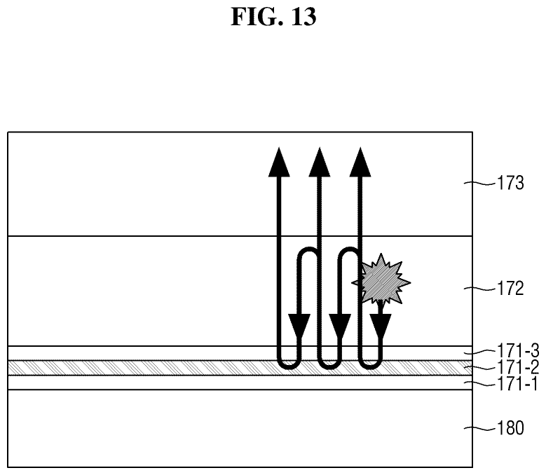

Next, with reference to FIGS. 13 to 16, the degree of resonance and the degree of light emission will be described when the first electrode includes and does not include a reflective layer.

FIGS. 13 to 16 correspond to the embodiments described with reference to FIGS. 1 to 7. That is, the configurations of FIGS. 13 to 16 illustrate a portion of the display device described in FIGS. 1 to 7 and detailed descriptions are omitted.

FIG. 13 is a schematic diagram to illustrating a strong resonance structure in which a reflective layer is disposed between two transparent conductive layers of the first electrode according to an embodiment. FIG. 13 illustrates a structure corresponding to the bottom portion 171-B of the first electrode 171 in the display device described in FIGS. 5 to 7.

Referring to FIG. 13, the light of the organic light emitting layer 172 emits the entire surface thereof and some of the emitted light is reflected from an interface between the second electrode 173 and the organic light emitting layer 172, and the reflected light is re-emitted by the reflective layer 171-2 of the first electrode 171, resulting in a relatively strong resonance effect.

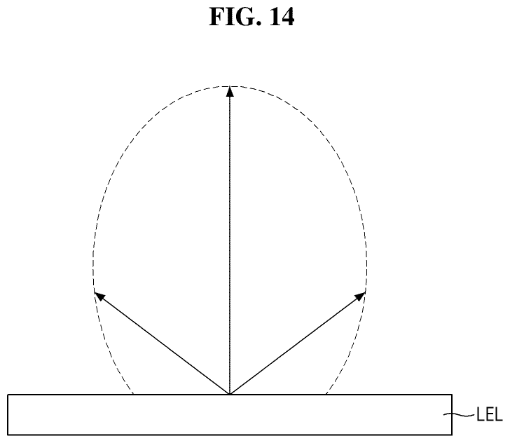

FIG. 14 is a schematic diagram illustrating light emitted from a light emitting element having a strong resonant structure as shown in FIG. 13. Referring to FIG. 14, light in the strong resonance structure has a strong directionality with a relatively strong light intensity in a specific direction and a narrow emission angle.

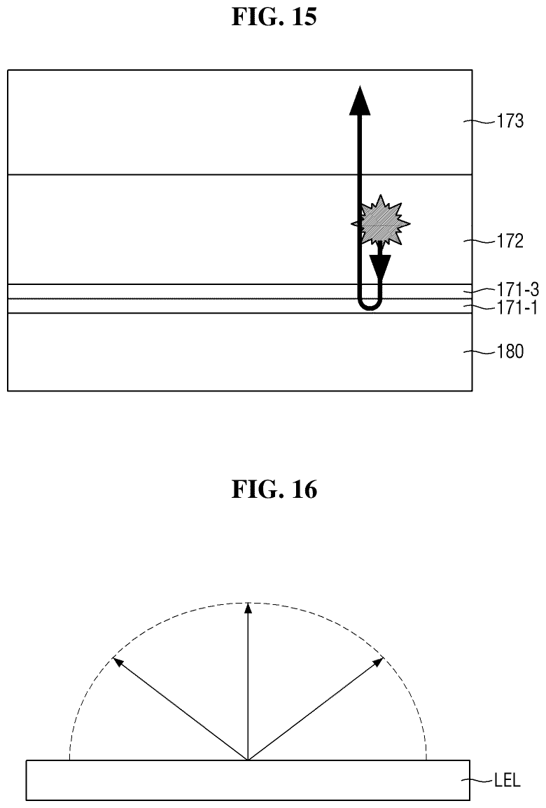

FIG. 15 is a schematic diagram illustrating the weak resonance effect of a structure in which the first electrode is arranged with two transparent conductive layers without a reflective layer according to an embodiment. FIG. 15 illustrates a structure corresponding to the inclined portion 171-W of the first electrode 171 in the display device described in FIGS. 5 to 7.

Referring to FIG. 15, the light of the organic light emitting layer 172 is emitted from the entire surface thereof and less light is reflected, resulting in a relatively weak resonance effect.

FIG. 16 is a schematic diagram illustrating light emitted from a light emitting element having the same structure as FIG. 15. Referring to FIG. 16, the light in the weak resonance structure has a weak directionality with a relatively weak light intensity in a specific direction and a wide emission angle.

Here, strong and weak light intensity and wide and narrow emission angle refer to relative intensity and angle to describe the comparison of light intensity and emission angle in the weak resonant structure and the strong resonant structure.

As discussed above, in an embodiment, the first electrode 171 includes an inclined portion 171-W and a bottom portion 171-B. Here, the inclined portion 171-W and the bottom portion 171-B have different reflectivities (i.e., different reflectances). Further, the inclined portion 171-W and the bottom portion 171-B may be composed of multiple levels. Additionally, the inclined portion 171-W and the bottom portion 171-B may have different resonance structures. The inclined portion 171-W may have a relatively low reflectivity compared to the bottom portion 171-B. For example, the inclined portion 171-W may have a first reflectance, and the bottom portion 171-B may have a second reflectance which is greater than the first reflectance. Furthermore, the inclined portion 171-W may have a weak resonance structure compared to the bottom portion 171-B. Thus, the effect of both improving the light extraction efficiency and improving the viewing angle characteristics of the display device may be achieved, as well as improving the lateral white angular dependence (WAD).

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device comprising:
a substrate including a display area and a non-display area;
a via layer having a recess in the display area, wherein the recess includes a bottom surface and an inclined side surface which is inclined at a first angle relative to the bottom surface, and the inclined side surface connects the bottom surface to a top surface of the via layer;
a first electrode including an inclined portion extending along the inclined side surface of the recess and a bottom portion extending along the bottom surface;
an organic light emitting layer disposed on the first electrode; and
a second electrode disposed on the organic light emitting layer,
wherein a first thickness of the inclined portion and a second thickness of the bottom portion are different, and
wherein the first thickness is measured in a first direction perpendicular to the inclined side surface of the recess, and the second thickness is measured in a second direction perpendicular to the bottom surface of the recess.

2. The display device of claim 1,
wherein the first electrode includes a first transparent conductive layer and a reflective layer,
wherein the first transparent conductive layer includes a first top portion disposed on the top surface of the via layer, a first inclined portion disposed on the inclined side surface of the recess, and a first bottom portion disposed on the bottom surface of the recess,
wherein the inclined portion includes the first inclined portion of the first transparent conductive layer, and
wherein the bottom portion includes the first bottom portion of the first transparent conductive layer.

3. The display device of claim 2,
wherein an entirety of the reflective layer does not overlap the inclined portion in the second direction.

4. The display device of claim 3,
wherein the first electrode further includes a second transparent conductive layer,
wherein the second transparent conductive layer includes a second top portion, a second inclined portion, and a second bottom portion, and
wherein the second top portion is disposed between the top surface of the via layer and the first top portion, the second inclined portion is disposed between the inclined side surface and the first inclined portion, and the second bottom portion is disposed between the entirety of the reflective layer and the bottom surface of the recess.

5. The display device of claim 3,
wherein the first inclined portion connects the first top portion to the first bottom portion, and
wherein the entirety of the reflective layer is disposed above or below the first bottom portion of the first transparent conductive layer.

6. The display device of claim 4,
wherein the first electrode further includes a top portion disposed on the top surface of the via layer.

7. The display device of claim 6,
wherein the top portion of the first electrode includes the first top portion of the first transparent conductive layer and the second top portion of the second transparent conductive layer, and
wherein the second top portion is disposed between the top surface of the via layer and the first top portion.

8. The display device of claim 2,
wherein the first transparent conductive layer is formed of one of Indium Tin Oxide (ITO), Indium Zinc Oxide (IZO), Zinc Oxide (ZnO), Indium Oxide (In₂O₃), Indium Gallium Oxide (IGO), and Aluminum Zinc Oxide (AZO).

9. The display device of claim 2,
wherein the reflective layer includes at least one selected from the group consisting of silver (Ag), magnesium (Mg), chromium (Cr), gold (Au), platinum (Pt), nickel (Ni), copper (Cu), tungsten (W), and aluminum (Al).

10. The display device of claim 1,
wherein the via layer includes a first via layer defining the inclined side surface of the recess, and a second via layer defining the bottom surface of the recess and disposed on a bottom surface of the first via layer.

11. The display device of claim 10,
wherein the recess is a through hole penetrating the first via layer and exposing a top surface of the second via layer.

12. The display device of claim 1, further comprising:
a thin film transistor disposed between the substrate and the via layer; and
a planarization layer disposed below the via layer and covering the thin film transistor,
wherein the first electrode is electrically connected to the thin film transistor.

13. The display device of claim 1, further comprising:
a pixel definition layer disposed on the via layer and including an opening exposing the first electrode,
wherein the second electrode is disposed within the opening; and
a thin film encapsulation layer disposed on the second electrode.

14. A display device comprising:
a substrate including a display area and a non-display area;
a via layer having a recess in the display area, where the recess includes a bottom surface and an inclined side surface which is inclined at a first angle relative to the bottom surface, and the inclined side surface connects the bottom surface to a top surface of the via layer;
a first electrode including an inclined portion extending along the inclined side surface of the recess and a bottom portion extending along the bottom surface of the recess;
an organic light emitting layer disposed on the first electrode; and
a second electrode disposed on the organic light emitting layer,
wherein a first reflectance of the inclined portion is different from a second reflectance of the bottom portion.

15. The display device of claim 14,
wherein the second reflectance of the bottom portion is greater than the first reflectance of the inclined portion.

16. The display device of claim 14,
wherein the inclined portion entirely surrounds the bottom portion.

17. The display device of claim 14,
wherein the bottom portion does not vertically overlap the inclined portion.

18. The display device of claim 14,
wherein the bottom portion is flatter than the inclined portion.

19. The display device of claim 14,
wherein the bottom portion includes a layer comprising at least one material selected from the group consisting of silver (Ag), magnesium (Mg), chromium (Cr), gold (Au), platinum (Pt), nickel (Ni), copper (Cu), tungsten (W), and aluminum (Al).

20. The display device of claim 14,
wherein the inclined portion includes a layer formed of at least one selected from the group consisting of Indium Tin Oxide (ITO), Indium Zinc Oxide (IZO), Zinc Oxide (ZnO), Indium Oxide (In₂O₃), Indium Gallium Oxide (IGO), and Aluminum Zinc Oxide (AZO).

21. A display device comprising:
a pixel definition layer disposed on a substrate, wherein the pixel definition layer has an opening extending from a top surface of the pixel definition layer to a bottom surface thereof;
a via layer interposed between a top surface of the substrate and the bottom surface of the pixel definition layer, wherein the via layer has a recess including a bottom surface and an inclined side surface which is inclined at a first angle relative to the bottom surface, and wherein the inclined side surface connects the bottom surface of the recess to the top surface of the via layer;
a first electrode including a transparent conductive layer and a reflective layer, wherein the transparent conductive layer includes a top portion disposed on the top surface of the via layer, an inclined portion disposed on the inclined side surface of the recess, and a bottom portion disposed on the bottom surface of the recess, and wherein the pixel definition layer covers an end portion of the top portion of the transparent conductive layer;
an organic light emitting layer disposed on the first electrode; and
a second electrode disposed on the organic light emitting layer,
wherein an entirety of the reflective layer contact the bottom portion of the transparent conductive layer.

22. The display device of claim 21,
wherein the entirety of the reflective layer is disposed between the bottom portion of the transparent conductive layer and the bottom surface of the recess.

23. The display device of claim 21,
wherein the bottom portion of the transparent conductive layer is disposed between the entirety of the reflective layer and the bottom surface of the recess.
